(19) United States
(12) Patent Application Publication
(10) Pub. No.: US 2018/0047781 A1
(43) Pub. Date: Feb. 15, 2018

(54) DOT MATRIX LIGHT-EMITTING DIODE LIGHT SOURCE FOR A WAFER-LEVEL MICRODISPLAY AND METHOD FOR FABRICATING THE SAME

(71) Applicant: Trend Lighting Corp., Taoyuan City (TW)

(72) Inventors: Jonathan Wang, Somerset, NJ (US); Peichin Hsieh, Taoyuan City (TW); Pei-Jih Wang, Taoyuan City (TW); Jerry Lin, Taoyuan City (TW)

(21) Appl. No.: 15/671,456

(22) Filed: Aug. 8, 2017

(30) Foreign Application Priority Data
Aug. 15, 2016 (TW) 105125891

(51) Int. Cl. H01L 27/15; H01L 33/38; H01L 33/00; H01L 33/58; H01L 33/60; H01L 33/32; H01L 33/44

(52) U.S. Cl. CPC H01L 27/156; H01L 33/32; H01L 33/387; H01L 33/44; H01L 33/58; H01L 33/60; H01L 33/0075; H01L 2933/0016

(57) ABSTRACT

A dot matrix light-emitting diode (LED) backlighting light source for a wafer-level microdisplay includes a substrate, multiple LED sets arranged at spaced intervals, a first electrode assembly, and a second electrode assembly. The multiple LED sets have multiple LEDs spaced apart and aligned in a first direction. The first electrode assembly and the second electrode assembly are formed on the multiple LED sets to connect the LEDs of the multiple LED sets in series along the first and second directions to constitute a dot matrix LED light source. Upon manufacture of a wafer-level microdisplay, the dot matrix LED light source can be directly packaged and assembled in a microdisplay, rendering the advantages of compact size and low production cost.

### BACKGROUND OF THE INVENTION

### 1. Field of the Invention

The present invention relates to a microdisplay and, more particularly, to a dot matrix light-emitting diode (LED) light source for a wafer-level microdisplay and a method for fabricating the same.

### 2. Description of the Related Art

Display devices at the earliest stage adopting raster scan theory of cathode ray tube (CRT) were born in 1922, enabling the ways of information dissemination to migrate from static texts to dynamic pictures of images and videos. Those early-stage displays had turned a new page back then in terms of information dissemination and recording.

However, CRT displays have the issues of being bulky and taking up too much space. Such size issue failed to be successfully tackled with numerous attempts been made until the emergence of liquid crystal displays. As liquid crystal materials are not self-illuminating, a backlight source is required for liquid crystal displays (LCD) to display information. To further diminish the size of displays, the blue light-emitting diode (LED) was developed in 1993. Subsequently, the white LED with higher luminance and lighting efficiency was introduced. In view of the advantages in small size, high luminance and high lighting efficiency, LEDs have been used as the backlight sources for LCDs, small displays and projectors.

Current technology involved with an LED light source can be implemented on a substrate, such as sapphire, gallium arsenide (GaAs) and gallium phosphide (GaP) substrates. An epitaxial layer is deposited on the substrate by epitaxial growth methods, such as metal organic chemical vapor deposition (MOCVD), vapor phase epitaxy (VPE), liquid phase epitaxy (LPE) or molecular beam epitaxy (MBE). The epitaxial layer can be divided into multiple LEDs spaced apart from each other by a photolithography process, an etching process, a lift-off process, a thin film deposition process, a metal deposition process, a spin process, and an alloy process for each LED to be equipped with electrodes for conducting power and packaging. A grinding process is further applied to thin the thickness of the substrate, a dicing process is applied to cut the multiple LEDs into multiple LED dices, and a packaging process is applied to the LED light source.

The foregoing photolithography process includes coating, exposure and development processes and serves to generate a photoresist layer on a surface of the epitaxial layer, a surface of a thin film or a surface of a thin metal film. The photoresist layer is formed by a photosensitive material. The exposure process serves to print a pattern of a mask having spaces arranged at spaced intervals on the photoresist layer. The etching process first etches away portions of the epitaxial layer not covered by the photoresist layer and then removes the photoresist layer for the epitaxial layer to form multiple LEDs spaced apart from each other by gaps, the thin film to form a pattern with spaces arranged at spaced intervals, or the thin metal film to form a pattern with spaces arranged at spaced intervals. The lift-off process removes the photoresist layer with an organic chemical solution for the thin metal film grown on the photoresist layer to he removed and portions of the thin metal film not covered by the photoresist layer to remain. The etching process may be a dry etching process or a wet etching process. Specifically, the dry etching process is an inductively coupled plasma reactive ion etching (ICP-RIE) and the wet etching process utilizes a chemical solution to perform etching via chemical reaction. The thin film deposition process deposits thin metal films on the multiple LEDs, and the photolithography process and the etching process are further applied to form electrodes. The thin film deposition process targets at growing non-metal thin film on surfaces of the multiple LEDs or portions among the multiple LEDs, and the photolithography process and the etching process are further applied to remove unnecessary portions of the thin film to serve the purpose of insulation, support or electrical conduction depending on the nature of the thin film. The alloy process forms good ohmic contact between the electrodes and the LEDs for electrical conduction through high-temperature baking.

There is another conventional LED light source, which has an epitaxial layer formed on a first substrate. The LED wafer fabrication process develops multiple LEDs on the epitaxial layer. A wafer bonding process bonds the multiple LEDs to a second substrate, which is highly thermally and electrically conductive or even transparent. A laser lift-off process is further applied to remove the first substrate to enhance efficacy of the multiple LEDs in operation, a grinding process is applied to thin the second substrate, the dicing process separates multiple LED dies from the wafer, and the packaging process packages the multiple LED dies to form the LED light source

Most LED light sources arranged in current LED displays take the form of arrays, such as seven-segment displays, dot matrix displays or regular LCD displays. As usually tending to be relatively large in size and limited by requirements of working accuracy for positioning and spatial arrangement, the packaged LED light sources are not applicable to small displays or are applicable to displays with limitations in size and the number of LED light sources equipped, which compromise display performance and operational convenience. Additionally, production cost of the LED array displays inevitably increases due to the array assembly processes.

### SUMMARY OF THE INVENTION

An objective of the present invention is to provide a dot matrix light-emitting diode (LED) light source for a wafer-level microdisplay and a method for fabricating the same, which allow multiple LEDs connected in series to constitute a dot matrix LED light source for assurance of compact size and low production cost without requiring additional processes in dicing, packaging and assembly.

To achieve the foregoing objective, the dot matrix LED light source for a wafer-level microdisplay includes a substrate, an LED epitaxial layer, a first electrode assembly, and a second electrode assembly.

The LED epitaxial layer is formed on a top surface of the substrate and has multiple LED sets formed on the LED epitaxial layer and arranged at spaced intervals. Each LED set has multiple LEDs aligned in a first direction. Each LED has a first epitaxial layer, a light-emitting layer and a second epitaxial layer. The first epitaxial layers of the LEDs of each LED set are connected to form a first epitaxial platform. The LEDs of the multiple LED sets that are aligned along any two adjacent rows in a second direction are aligned with each other.

The first electrode assembly has multiple first electrodes. Each first electrode is formed on a top surface of the first epitaxial platform of a corresponding LED set to connect in series to the LEDs of the corresponding LED set.

The second electrode assembly has multiple second electrodes. The second electrodes are each respectively formed on top surfaces of the LEDs of the multiple LED sets aligned in a corresponding row along the second direction to connect the LEDs of the multiple LED sets aligned in the corresponding row along the second direction.

From the foregoing description, manufacturers of microdisplays can connect the first electrode assembly and the second electrode assembly to the multiple LEDs that are arranged at spaced intervals to constitute a dot matrix LED light source, which can be directly packaged and assembled in a wafer-level microdisplay. As there is no additional dicing, packaging and array assembly involved for producing the microdisplay, the microdisplay can be implemented at a reduced size and lower production cost.

To achieve the foregoing objective, the method for fabricating a dot matrix light-emitting diode (LED) light source for a wafer-level microdisplay includes:

preparing a substrate;

forming an LED epitaxial layer on a top surface of the substrate;

forming multiple LED sets arranged at spaced intervals by applying an LED wafer fabrication process to the LED epitaxial layer, wherein each LED set has multiple LEDs aligned in a first direction, each LED set has a first epitaxial platform, and the LEDs of the multiple LED sets that are aligned along any two adjacent rows in a second direction are aligned with each other;

forming a first electrode assembly on top surfaces of the first epitaxial platforms of the multiple LED sets; and

forming a second electrode assembly on top surfaces of the LEDs of the multiple LED sets aligned in the second direction.

The foregoing fabrication method is involved with fabrication processes of forming the LED epitaxial layer on the substrate, forming the multiple LED sets arranged at spaced intervals on the LED epitaxial layer through the LED wafer fabrication process. Each LED set includes the multiple LEDs and the first epitaxial platform, such that the first electrode assembly can be formed on the first epitaxial platform and the second electrode assembly can be formed on the LEDs of the multiple LED sets aligned in the second direction to constitute a dot matrix LED light source, thereby fulfilling the implementation of a wafer-level microdisplay using the dot matrix LED light source.

To achieve the foregoing objective, the dot matrix light-emitting diode (LED) light source for a wafer-level microdisplay includes a substrate, an LED epitaxial layer, a bonding layer, a first electrode assembly, and a second electrode assembly.

The LED epitaxial layer is formed on a top surface of the substrate and has multiple LED sets formed on the LED epitaxial layer and arranged at spaced intervals. Each LED set has multiple LEDs aligned in a first direction. Each LED has a first epitaxial layer, a light-emitting layer and a second epitaxial layer. The first epitaxial layers of the LEDs of each LED set are connected to form a first epitaxial platform. The LEDs of the multiple LED sets that are aligned along any two adjacent rows in a second direction are aligned with each other.

The bonding layer is formed between the substrate and the multiple LED sets.

The first electrode assembly is formed between the bonding layer and the multiple LED sets and has multiple first electrodes each of which is formed between a corresponding LED set and the bonding layer to connect in series to the LEDs of the corresponding LED set.

The second electrode assembly has multiple second electrodes. The second electrodes are each respectively formed on top surfaces of the LEDs of the multiple LED sets aligned in a corresponding row along the second direction to connect the LEDs of the multiple LED sets aligned in the corresponding row along the second direction.

From the foregoing description, manufacturers of microdisplays can connect the first electrode assembly and the second electrode assembly to the multiple LEDs that are arranged at spaced intervals to constitute a dot matrix LED light source. As there is no additional dicing, packaging and array assembly involved for producing the microdisplay, the microdisplay can be implemented at a reduced size and lower production cost.

To achieve the foregoing objective, the method for fabricating a dot matrix light-emitting diode (LED) light source for a wafer-level microdisplay includes:

preparing a first substrate;

forming an LED epitaxial layer on a top surface of the substrate;

forming a first electrode assembly on a top surface of the LED epitaxial layer; and

preparing a second substrate;

forming a bonding layer on a top surface of the second substrate;

bonding the first electrode assembly to a top surface of the bounding layer;

forming multiple LED sets arranged at spaced intervals by applying an LED wafer fabrication process to the LED epitaxial layer, wherein each LED set has multiple LEDs aligned in a first direction, each LED set has a first epitaxial platform, and the LEDs of the multiple LED sets that are aligned along any two adjacent rows in a second direction are aligned with each other; and

forming a second electrode assembly on top surfaces of the LEDs of the multiple LED sets aligned in the second direction.

The foregoing fabrication method is involved with fabrication processes of forming the LED epitaxial layer on the first substrate, forming the first electrode assembly on the LED epitaxial layer, then providing the second substrate, forming the bonding layer on the second substrate, bonding the first electrode assembly to the bonding layer, and removing the second substrate with a laser lift-off or etching technique, such that an LED wafer fabrication process is applied to the LED epitaxial layer to form the multiple LED sets arranged at spaced intervals on the LED epitaxial layer, and the second electrode assembly can be formed on the LEDs of the multiple LED sets aligned in the second direction to constitute a dot matrix LED light source, thereby fulfilling the implementation of a wafer-level microdisplay using the dot matrix LED light source.

Other objectives, advantages and novel features of the invention will become more apparent from the following detailed description when taken in conjunction with the accompanying drawings.

### BRIEF DESCRIPTION OF THE DRAWINGS

FIG. 1 is a top view of a first embodiment of a dot matrix LED light source for a wafer-level microdisplay in accordance with the present invention;

FIG. 2 is a cross-sectional view of the dot matrix LED light source in FIG. 1 taken along line 2-2;

FIG. 3 is a cross-sectional view of the dot matrix LED light source in FIG. 1 taken along line 3-3;

FIG. 4 is a cross-sectional view of the dot matrix LED light source in FIG. 3 fabricated under a first fabrication process;

FIG. 5 is a cross-sectional view of the dot matrix LED light source in FIG. 3 fabricated under a second fabrication process;

FIG. 6 is a cross-sectional view of the dot matrix LED light source in FIG. 3 fabricated under a third fabrication process;

FIG. 7 is a cross-sectional view of the dot matrix LED light source in FIG. 3 fabricated under a fourth fabrication process;

FIG. 8 is another top view of the dot matrix LED light source in FIG. 1;

FIG. 9 is a top view of a second embodiment of a dot matrix LED light source for a wafer-level microdisplay in accordance with the present invention;

FIG. 10 is a cross-sectional view of the dot matrix LED light source in FIG. 9 taken along line 10-10;

FIG. 11 is a cross-sectional view of the dot matrix LED light source in FIG. 10 fabricated under a first fabrication process;

FIG. 12 is a cross-sectional view of the dot matrix LED light source in FIG. 10 fabricated under a second fabrication process;

FIG. 13 is a cross-sectional view of the dot matrix LED light source in FIG. 10 fabricated under a third fabrication process;

FIG. 14 is a cross-sectional view of the dot matrix LED light source in FIG. 10 fabricated under a fourth fabrication process;

FIG. 15 is a cross-sectional view of the dot matrix LED light source in FIG. 10 fabricated under a fifth fabrication process;

FIG. 16 is a cross-sectional view of the dot matrix LED light source in FIG. 10 fabricated under a sixth fabrication process; and

FIG. 17 is another top view of the dot matrix LED light source in FIG. 9.

### DETAILED DESCRIPTION OF THE INVENTION

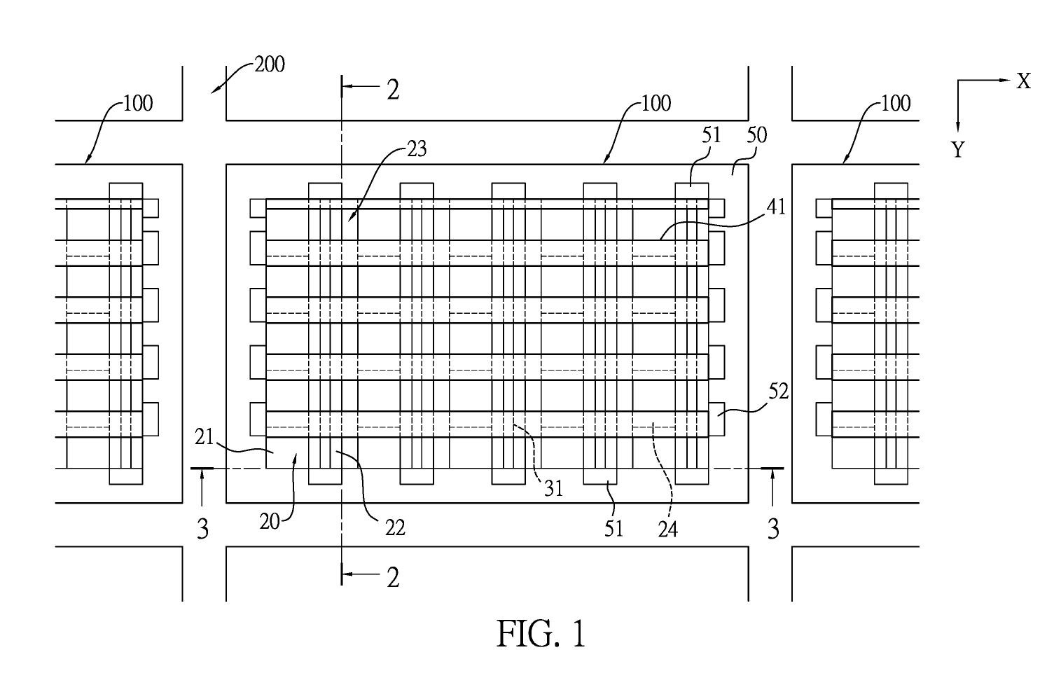

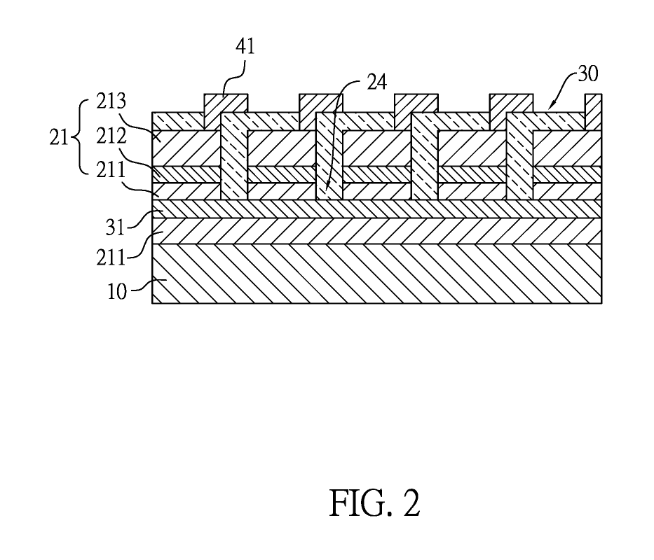

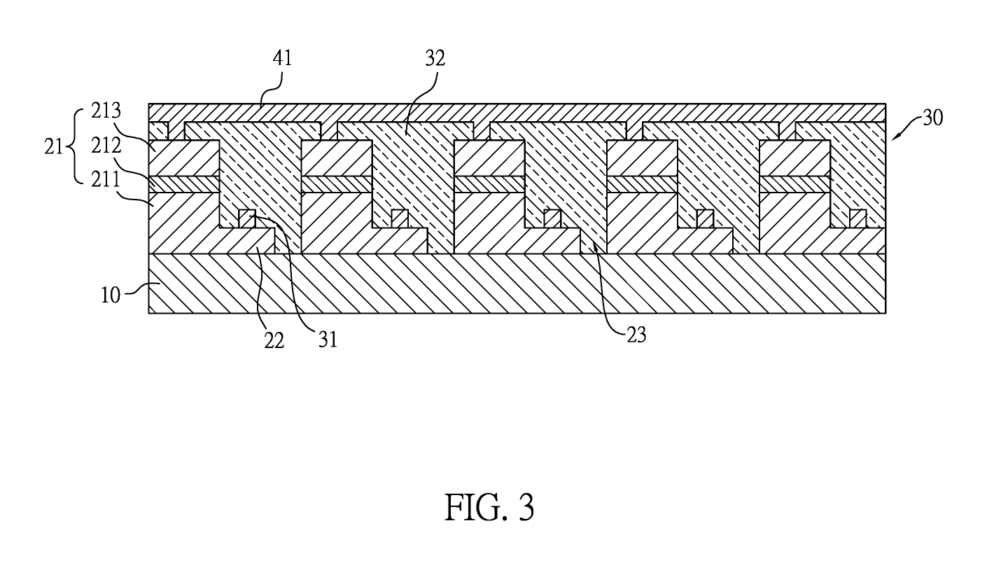

With reference to FIGS. 1-3, a first embodiment of a dot matrix light-emitting diode (LED) light source 100 for a wafer-level microdisplay in accordance with the present invention includes a first substrate 10, multiple LED sets 20, a first electrode assembly 30, and a second electrode assembly.

The multiple LED sets 20 are arranged at spaced intervals. Each LED set 20 has multiple LEDs 21 spaced apart from each other and aligned in a first direction (Y-axis direction). Each LED 21 has a first epitaxial layer 211, a light-emitting layer 212 and a second epitaxial layer 213, which are sequentially formed on a top surface of the first substrate 10. The first epitaxial layers 211 of the LEDs 21 of each LED set 20 are mutually connected to form a first epitaxial platform 22. The LEDs 21 of the multiple LED sets 20 that are aligned along any two adjacent rows in a second direction (X-axis direction) are aligned with each other, such that the LEDs 21 of the multiple LED sets 20 are aligned in the form of a matrix. The multiple LED sets 20 further have multiple first slots 23 and multiple second slots 24. Each first slot 23 is formed between adjacent two of the multiple LED sets 20. Each second slot 24 is formed between the LEDs 21 of the LED sets 20 aligned in two adjacent rows along the second direction (X-axis direction). The multiple first slots 23 and the multiple second slots 24 are aligned in the first direction (Y-axis direction) and the second direction (X-axis direction) respectively. The first direction (Y-axis direction) is perpendicular to the second direction (X-axis direction). In the present embodiment, the first substrate 10 is a transparent substrate.

The first electrode assembly 30 includes multiple first electrodes 31 each of which is formed on a top surface of the first epitaxial platform 22 of a corresponding LED set 20 to connect the LEDs 21 of the corresponding LED set 20 in series, and the second electrode assembly includes multiple second electrodes 41 each respectively formed on top surfaces of the LEDs 21 of the multiple LED sets 20 aligned in a corresponding row along the second direction (X-axis direction) to connect the LEDs 21 of the multiple LED sets 20 aligned in the corresponding row along the second direction (X-axis direction), such that at least one dot matrix LED light source 100 can be constituted.

In the present embodiment, a packaging area 50 is formed around a perimeter of the multiple LED sets 20. The packaging area 50 includes a first area and a second area. The first area is aligned in the first direction (Y-axis direction) with multiple first electrode terminals 51 formed on the first area and connecting with the respective first electrodes 31 of the first electrode assembly 30, and the second area is aligned in the second direction (X-axis direction) with multiple second electrode terminals 52 formed on the second area and connecting with the respective second electrodes 41 of the second electrode assembly, facilitating subsequent packaging of each LED light source 100. In the present embodiment, a scribe channel 200 is formed between each adjacent two columns of the multiple dot matrix LED light sources 100 for each dot matrix LED light source 100 to be easily separated by a dicing process and packaged.

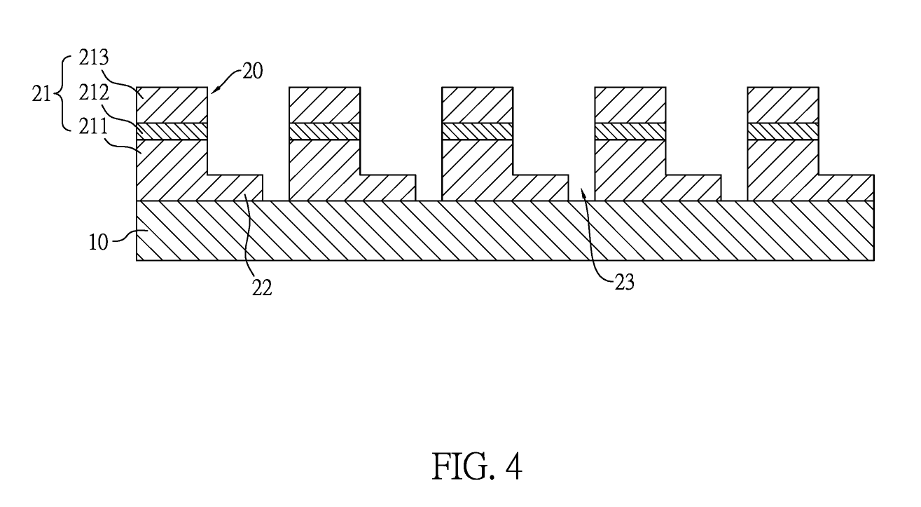

To depict a method for fabricating the dot matrix LED light source 100, with reference to FIGS. 1 and 4, an LED epitaxial layer is formed on a surface of the first substrate 10 by way of epitaxial growth. The multiple LED sets 20 that are spaced apart from each other are formed on the LED epitaxial layer through an LED wafer fabrication process. Each LED set 20 includes the multiple LEDs 21 aligned along a straight line in the first direction (Y-axis direction). Each LED 21 has the first epitaxial layer 211, the light-emitting layer 212 and the second epitaxial layer 213 sequentially stacked on the surface of the first substrate 10. The first epitaxial layers 211 of the multiple LEDs 21 of each LED set 20 are mutually connected to form the first epitaxial platform 22. Each first slot 23 is formed between corresponding adjacent two of the multiple LED sets 20. Each second slot 24 is formed between the LEDs 21 of the LED sets 20 aligned in two adjacent rows along the second direction (X-axis direction). In the present embodiment, the LED wafer fabrication process adopts and combines a photolithography process, an etching process, a lift-off process, a thin film deposition process, a coating process, a wafer bonding process, a wafer laser de-bonding process, a laser lift-off process, a metal deposition process, and an alloy process. The LED epitaxial layer may be made from gallium nitride (GaN), indium gallium nitride (InGaN) or aluminum gallium indium nitride (AlGaInN). The size of each LED 21 is in a range of 1 μm˜500 μm.

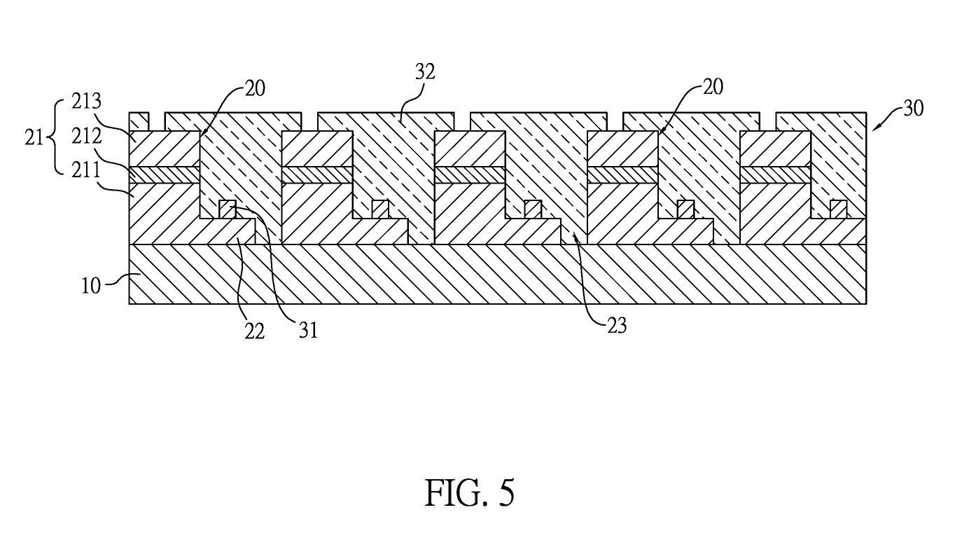

With reference to FIGS. 1 and 5, the first electrode assembly 30 includes the multiple first electrodes 31 and a first insulation layer 32. Each first electrode 31 is formed on a top surface of the first epitaxial platform 22 of a corresponding LED set 20 to connect the LEDs 21 of the corresponding LED set 20 in series.

The first insulation layer 32 is formed on top surfaces of the second epitaxial layers 213 of the multiple LED sets 20 and the first electrodes 31 and is filled in the first slots 23 to protect the multiple LED sets 20 and the first electrodes 31 and support the second electrode assembly with a portion of a top surface of the second epitaxial layer 213 of each LED 21 exposed. In the present embodiment, the first insulation layer 32 is formed by silicon dioxide (SiO₂) or silicon nitride (Si₃N₄).

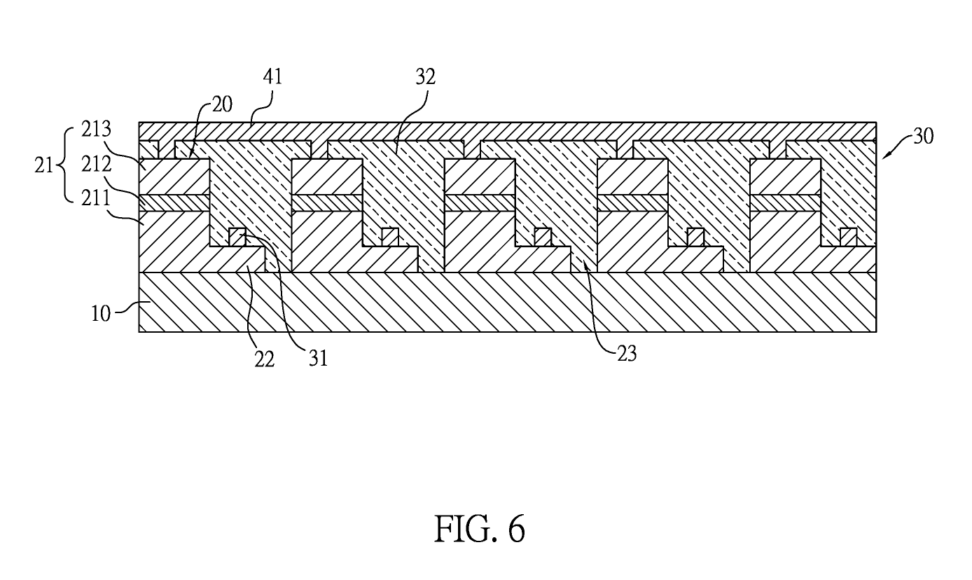

With reference to FIGS. 1, 6 and 7, the second electrode assembly includes the multiple second electrodes 41, a second insulation layer 42 and a grating layer. Each second electrode 41 is formed on a top surface of the first insulation layer 32 and the top surfaces of the second epitaxial layers 213 of the LEDs 21 of the multiple LED sets 20 aligned in a corresponding row along the second direction (X-axis direction) to connect the LEDs 21 aligned in the corresponding row along the second direction (X-axis direction). The multiple second electrodes 41 cover the respective second slots 24 to prevent light emitted from the LEDs 21 of the multiple LED sets 20 from coming out from the multiple second slots 24 in an upward direction and effectively concentrate light emitted from the LEDs 21. The multiple first electrodes 31, the multiple second electrodes 41 and the LEDs 21 of the multiple LED sets 20 are formed with good electric conductivity by using the alloy process. In the present embodiment, each first electrode 31 is formed by overlapping titanium, aluminum and gold in layers of Ti/Al/Ti/Au or overlapping platinum, titanium and gold in layers of Pt/Ti/Pt/Au.

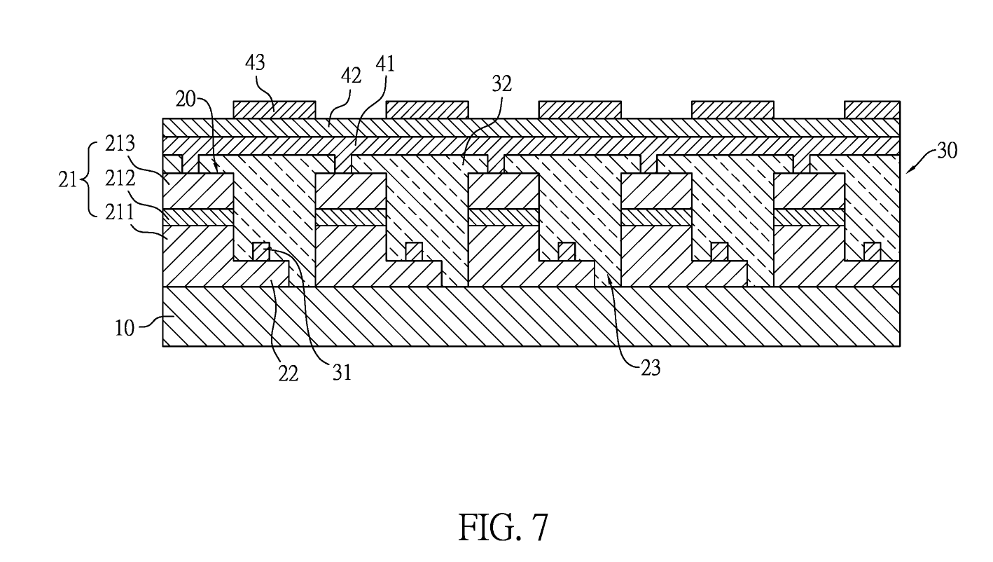

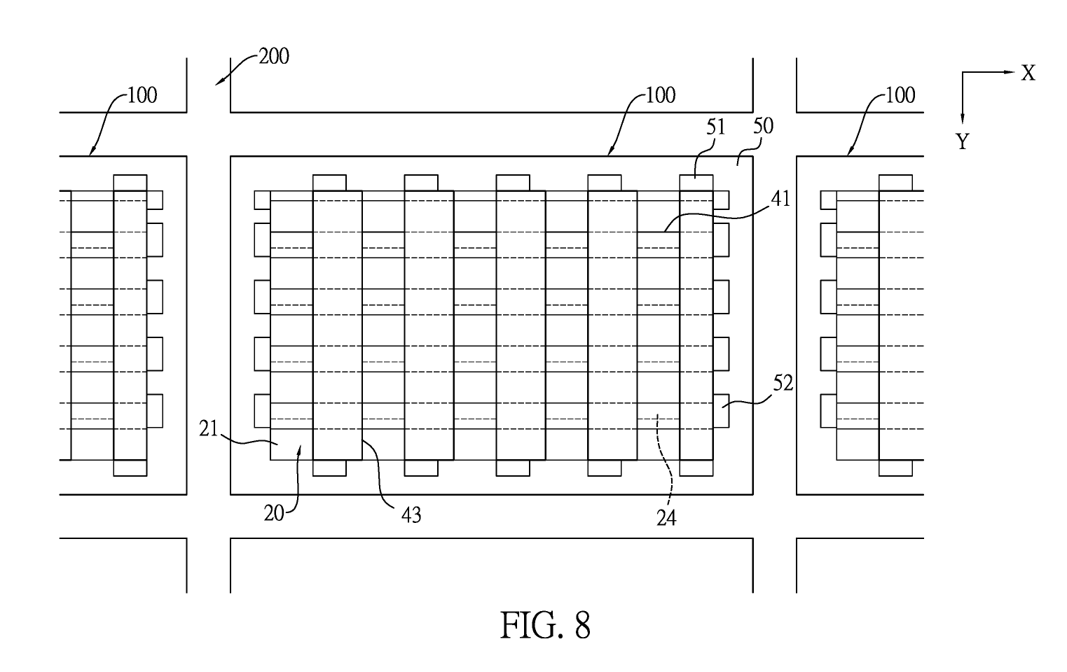

With reference to FIGS. 7 and 8, the second insulation layer 42 is formed on top surfaces of the multiple second electrodes 41 and the first insulation layer 32 to protect the multiple second electrodes 41 and support the grating layer. The grating layer is further formed on a top surface of the second insulation layer 42 and has multiple gratings 43. The multiple gratings 43 respectively block the first epitaxial platforms 22 and the multiple first slots 23 to prevent light emitted from the LEDs 21 of the multiple LED sets 20 from coming out from the multiple first slots 23 and the first epitaxial platforms 22 in an upward direction and effectively concentrate light emitted from the LEDs 21. In the present embodiment, the second insulation layer 32 is formed by silicon dioxide (SiO₂) or silicon nitride (Si₃N₄), and the gratings are formed by opaque materials.

The LEDs 21 of the multiple LED sets 20 are connected in series through the first electrodes 31 and the second electrodes 41 to constitute the dot matrix LED light source 100. During manufacture of a wafer-level microdisplay, the dot matrix LED light source 100 just needs to be packaged in a microdisplay. Thus, the LEDs 21 are unnecessarily cut into separate LEDs 21 first before packaging and assembly. Therefore, cutting expense can be reduced. As no additional packaging and array assembly are required, compact size of the LEDs can be secured to facilitate subsequent assembly.

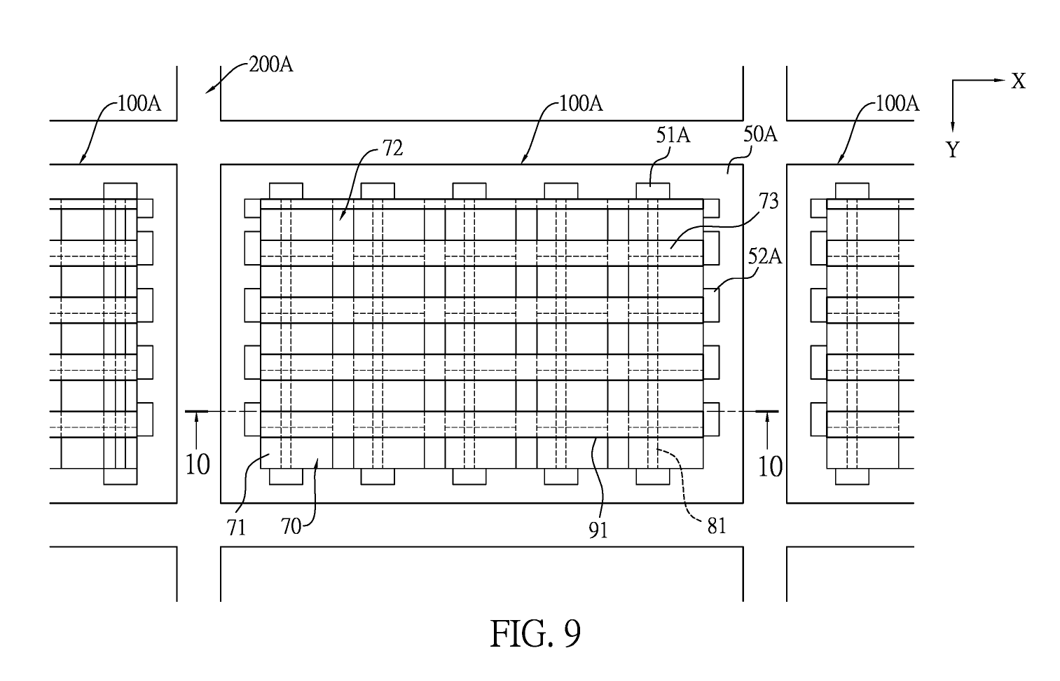

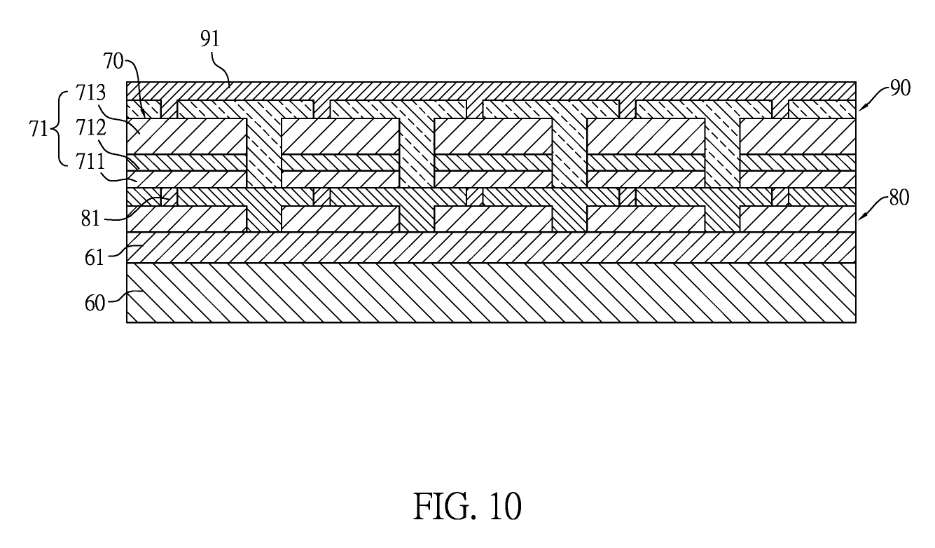

With reference to FIGS. 9 and 10, a second embodiment of a dot matrix LED light source 100A for a wafer-level microdisplay in accordance with the present invention includes a first substrate 60, a bonding layer 61, multiple LED sets 70, a first electrode assembly 80 and a second electrode assembly 90.

The multiple LED sets 70 are arranged at spaced intervals. Each LED set 70 has multiple LEDs 71 spaced apart from each other and aligned in a first direction (Y-axis direction). Each LED 71 has a first epitaxial layer 711, a light-emitting layer 712 and a second epitaxial layer 713, which are sequentially formed on a top surface of the first substrate 60. The first epitaxial layers 711 of the multiple LEDs 71 are mutually connected. The LEDs 71 of the multiple LED sets 70 that are aligned along any two adjacent rows in the second direction (X-axis direction) are aligned with each other, such that the LEDs 71 of the multiple LED sets 70 are aligned in the form of a matrix. There are multiple first slots 72 and multiple second slots 73. Each first slot 72 is formed between adjacent two of the multiple LED sets 20. Each second slot 73 is formed between the LEDs 71 of the LED sets 70 aligned in two adjacent rows along the second direction (X-axis direction). The multiple first slots 72 and the multiple second slots 73 are aligned in the first direction (Y-axis direction) and the second direction (X-axis direction) respectively. The first direction (Y-axis direction) is perpendicular to the second direction (X-axis direction). In the present embodiment, the first substrate 60 is a transparent substrate with high thermal dissipation and high conductivity, and the size of each LED is in a range of 1 μm˜500 μm.

The first electrode assembly 80 is formed between the bonding layer 61 and the multiple LED sets 70 and includes multiple first electrodes 81 each of which is formed between a corresponding LED set 70 and the bonding layer 61 to connect the LEDs 71 of the corresponding LED set 70 in series. The second electrode assembly 90 includes multiple second electrodes 91 each respectively formed on top surfaces of the LEDs 71 of the multiple LED sets 70 aligned in a corresponding row along the second direction (X-axis direction) to connect the LEDs 71 of the multiple LED sets 70 aligned in the corresponding row along the second direction (X-axis direction), such that at least one dot matrix LED light source 100A can be constituted.

In the present embodiment, a packaging area 50A is formed around a perimeter of the multiple LED sets 70. The packaging area 50A includes a first area and a second area. The first area is aligned in the first direction (Y-axis direction) with multiple first electrode terminals 51A formed on the first area and connecting with the respective first electrodes 81 of the first electrode assembly 80, and the second area is aligned in the second direction (X-axis direction) with multiple second electrode terminals 52A formed on the second area and connecting with the respective second electrodes 91 of the second electrode assembly 90, facilitating subsequent packaging of each LED light source 100A. In the present embodiment, a scribe channel 200A is formed between each adjacent two columns of multiple dot matrix LED light sources 100A for each dot matrix LED light source 100A to be easily separated by a dicing process and packaged.

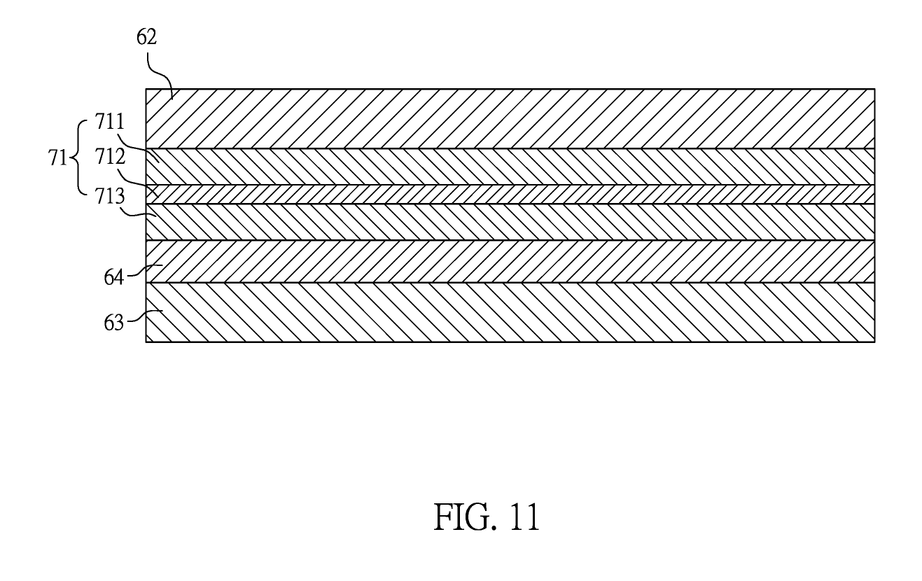

With reference to FIG. 11, a second substrate 62 is prepared first, and an LED epitaxial layer is formed on a surface of the second substrate 62 by way of epitaxial growth. The LED epitaxial layer includes a first epitaxial layer 711, a light-emitting layer 712 and a second epitaxial layer 713 sequentially stacked on the surface of the first substrate 62. A third substrate 63 is further prepared. A bonding layer 64 is then formed on a top surface of the third substrate 63. A wafer bonding fabrication process is used to bond a surface of the second epitaxial layer 713 to a surface of the bonding layer 64. A laser lift-off technique is applied to remove the second substrate 62 for a surface of the first epitaxial layer 711 to be exposed. In the present embodiment, the bonding layer 64A is formed by indium (In)/tin (Sn)/gold (Au)/Silicon (Si)/Germanium (Ge) or Bzocyclobutene (BCB) adhesive or spin-on glass (SOG).

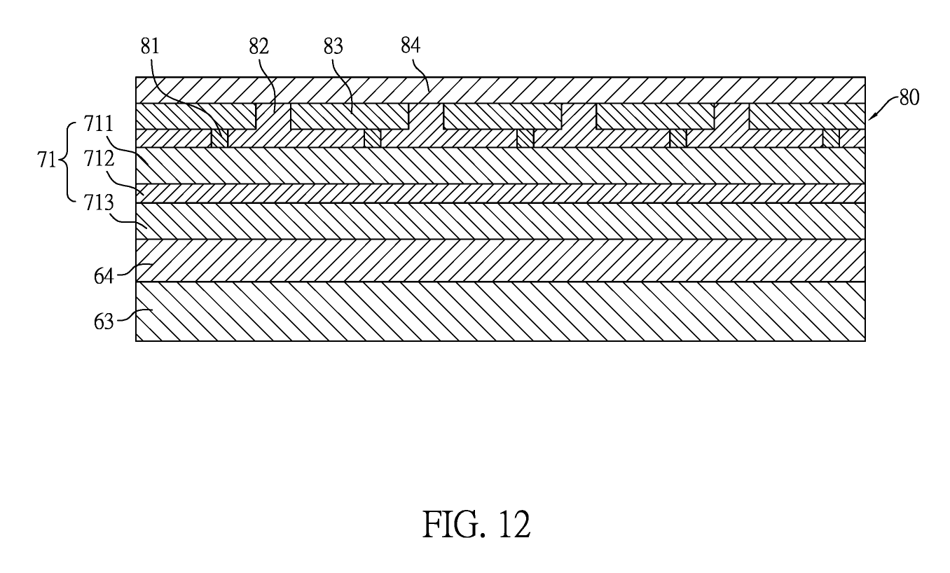

With reference to FIG. 12, the first electrode assembly 80 includes the multiple first electrodes 81, a first insulation layer 82, a reflective layer and a second insulation layer 84. The multiple first electrodes 81 are formed on a top surface of the first epitaxial layer 711. The first insulation layer 82 is formed on the top surface of the first epitaxial layer 711 and portions between each adjacent two of the multiple first electrodes 81 to support the reflective layer. Top surfaces of the multiple LED sets 70 are partially exposed for the multiple first electrodes 81 to be respectively formed on the exposed portions of the top surfaces of the multiple LED sets 70. The reflective layer is formed on the top surfaces of the multiple first electrodes 81 and a top surface of the first insulation layer 82. The reflective layer has multiple reflective strips 83 correspondingly covering the respective first electrodes 81 to reflect light emitted from the multiple LED sets 70. The second insulation layer 84 is formed on a top surface of the reflective layer and the top surface of the first insulation layer 82 to protect the reflective layer. A top surface of the second insulation layer 84 is flat.

In the present embodiment, the first insulation layer 82 and the second insulation layer are formed by silicon dioxide (SiO₂) or silicon nitride (Si₃N₄), the reflective strips 83 are formed by silver (Ag), aluminum (Al) or distributed Bragg reflector (DBR), and the first electrodes 81 are formed by overlapping titanium (Ti), aluminum (Al) and gold (Au) in layers of Ti/Al/Ai/Au or overlapping platinum (Pt), titanium (Ti), gold (Au) in layers of Pt/Ti/Pt/Au.

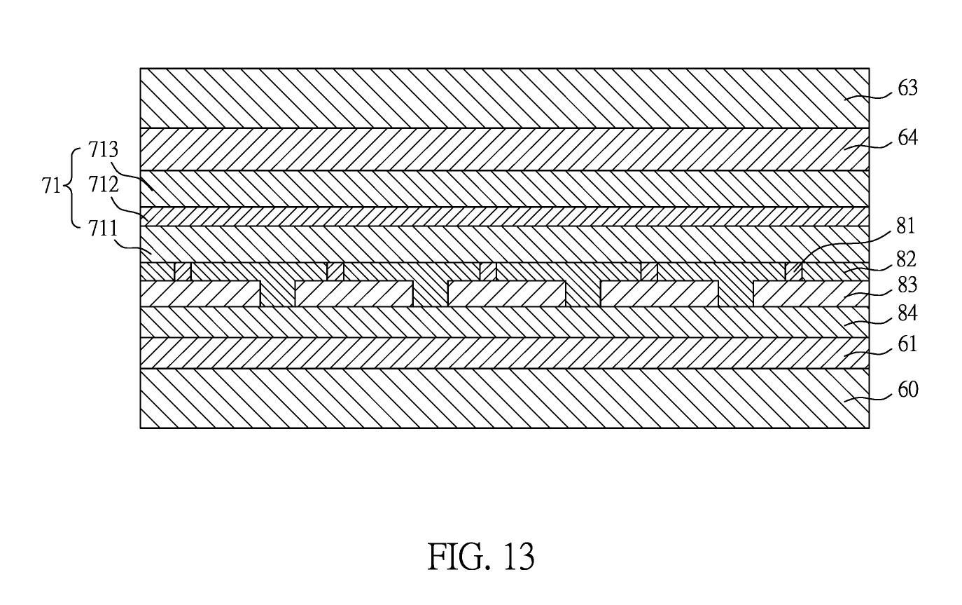

With reference to FIG. 13, the first substrate 60 is prepared first, the bonding layer 61 is formed on the top surface of the first substrate 60, a bottom surface of the second insulation layer 84 is bonded to the top surface of the bonding layer 61, and the bonding layer 64 and the third substrate 63 are removed to expose the top surface of the second epitaxial layer 713.

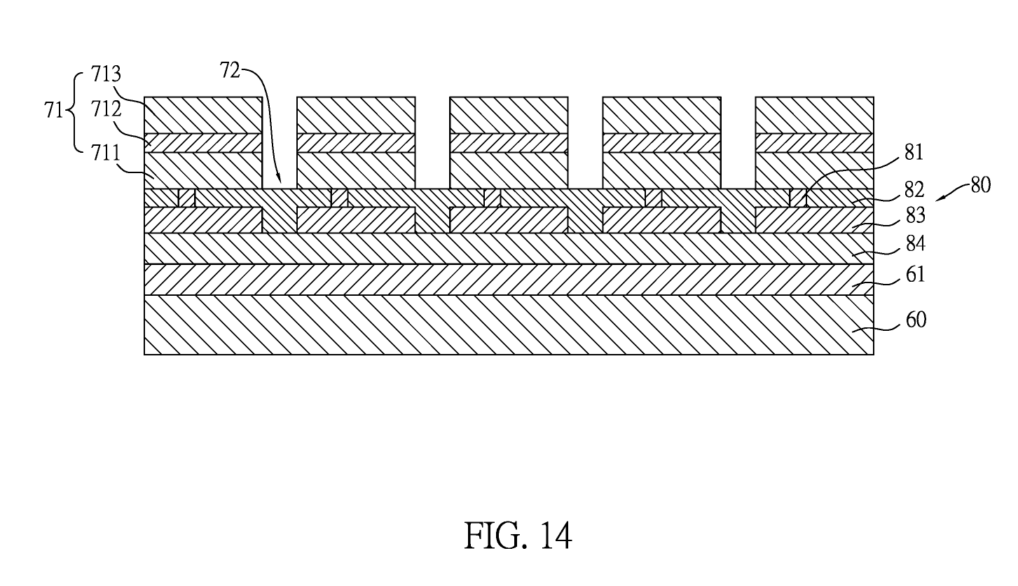

With reference to FIGS. 9 and 14, the LED epitaxial layer is fabricated into the multiple LED sets 70 spaced apart from each other. The multiple LED sets 70 include the LEDs aligned in the first direction (Y-axis direction) with the first epitaxial layers 711 of the LEDs 71 mutually connected. Each first slot 72 is formed between adjacent two of the multiple LED sets 70. Each second slot 73 is formed between the LEDs of the multiple LED sets 70 aligned in two adjacent rows along the second direction (X-axis direction).

The multiple LED sets 70 respectively correspond to the multiple first electrodes 81 and the multiple reflective strips 83. Each first electrode 81 is connected with the LEDs 71 of a corresponding LED set 70. The reflective strips 83 match and cover the respective LED sets 70 to reflect light emitted from the multiple LED sets 70 to come out in an upward direction.

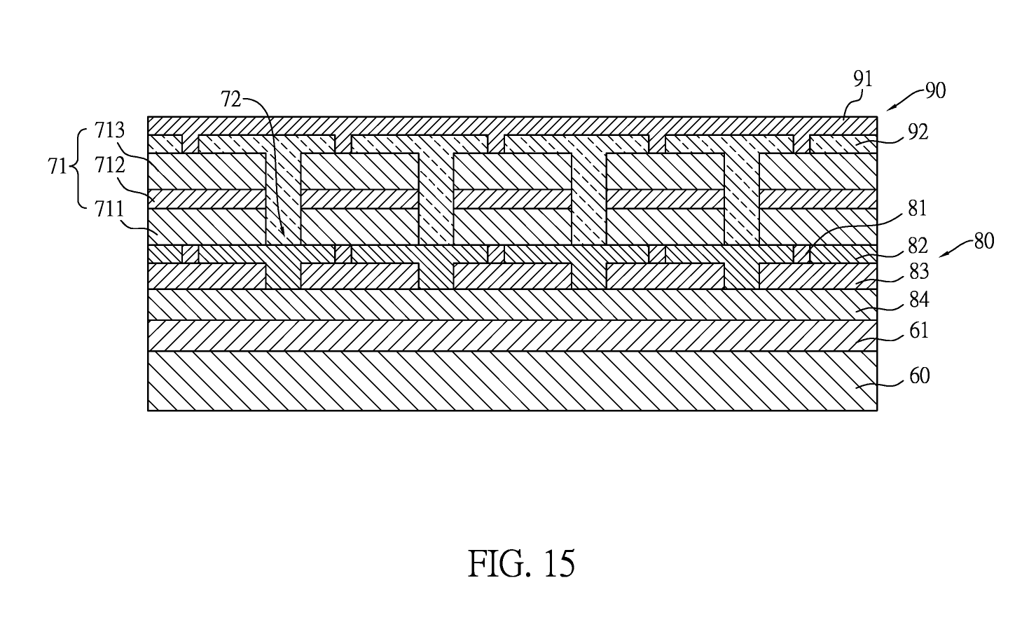

With reference to FIG. 15, the second electrode assembly 90 includes the multiple second electrodes and a first insulation layer 92. The first insulation layer 92 is formed on top surfaces of the LEDs 71 of the multiple LED sets 70 aligned in the second direction (X-axis direction), is filled in the multiple first slots 72 and the multiple second slots 73 to protect the LEDs 71 of the multiple LED sets 70 aligned in the second direction (X-axis direction) and support the multiple second electrodes 91. The second epitaxial layers 713 of the LEDs 71 aligned in the second direction (X-axis direction) are partially exposed. The multiple second electrodes 91 are connected in series to the respective LEDs aligned in the second direction (X-axis direction) and cover the respective second slots 73. In the present embodiment, each second electrode is formed by overlapping titanium, aluminum and gold in layers of Ti/Al/Ti/Au or overlapping platinum, titanium and gold in layers of Pt/Ti/Pt/Au.

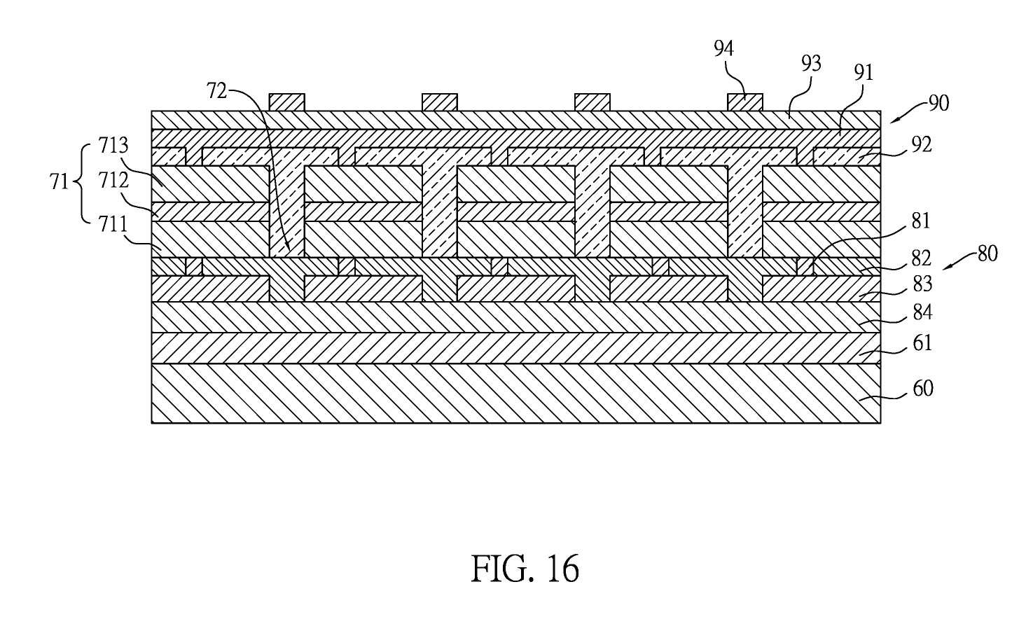

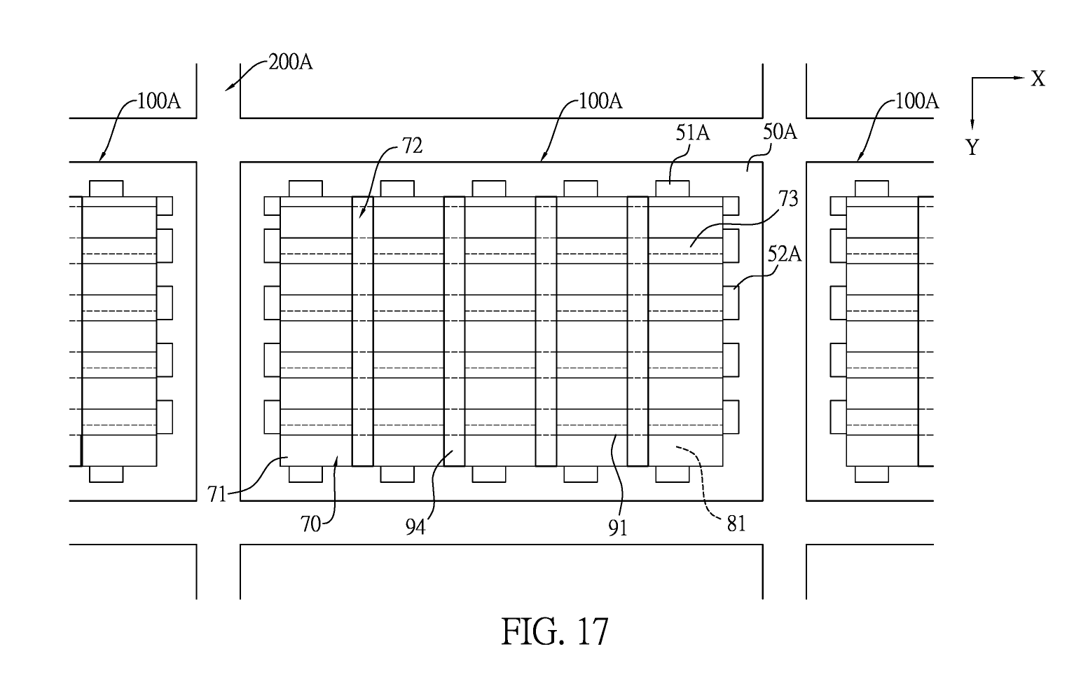

With reference to FIGS. 16 and 17, the second electrode assembly 90 further includes a second insulation layer 93 and a grating layer. The second insulation layer 93 is formed on top surfaces of the second electrodes 91 and the first insulation layer 92 to protect the second electrodes 91 and support the grating layer. The top surfaces of the LEDs 71 of the LED sets 70 aligned in the second direction (X-axis direction) are partially exposed for the second electrodes 91 to be respectively formed on the partially exposed portions of the top surfaces of the LEDs 71. The grating layer is formed on a top surface of the second insulation layer 93 and includes multiple gratings 94 covering the respective first slots to prevent light emitted from the multiple LEDs 71 aligned in the second direction (X-axis direction) from coming out from the first slots 72 and effectively concentrate light emitted from the LEDs 71. In the present embodiment, the first insulation layer 92 and the second insulation layer 93 are formed by silicon dioxide (SiO₂) or silicon nitride (Si₃N₄), and the multiple gratings 94 are formed by an opaque material.

The dot matrix LED light source 100A can be constructed by virtue of the multiple first electrodes 81 and the multiple second electrodes 91 respectively connected in series to the LEDs 71 of the multiple LED sets 70. During manufacture of a wafer level microdisplay, the dot matrix LED light source 100A just needs to be packaged in a microdisplay and the wafer level microdisplay is formed. Thus, the LEDs 71 are unnecessarily cut into separate LEDs 71 before packaging and assembly. Therefore, cutting expense can be reduced. As no additional packaging and array assembly are required, compact size of the LEDs can be secured to facilitate subsequent assembly.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A dot matrix light-emitting diode (LED) light source for a wafer-level microdisplay, comprising:
a substrate;
an LED epitaxial layer formed on a top surface of the substrate and having multiple LED sets formed on the LED epitaxial layer and arranged at spaced intervals, wherein each LED set has multiple LEDs aligned in a first direction, each LED has a first epitaxial layer, a light-emitting layer and a second epitaxial layer, the first epitaxial layers of the LEDs of each LED set are connected to form a first epitaxial platform, and the LEDs of the multiple LED sets that are aligned along any two adjacent rows in a second direction are aligned with each other;
a first electrode assembly having multiple first electrodes, wherein each first electrode is formed on a top surface of the first epitaxial platform of a corresponding LED set to connect in series to the LEDs of the corresponding LED set; and
a second electrode assembly having multiple second electrodes, wherein the second electrodes are each respectively formed on top surfaces of the LEDs of the multiple LED sets aligned in a corresponding row along the second direction to connect the LEDs of the multiple LED sets aligned in the corresponding row along the second direction.

2. The dot matrix LED light source as claimed in claim 1, wherein the first electrode assembly further includes a first insulation layer formed between each adjacent two of the multiple LED sets and top surfaces of the first electrodes with the top surface of each LED partially exposed for the multiple second electrodes of the second electrode assembly to be formed on the partially exposed top surface of the LED.

3. The dot matrix LED light source as claimed in claim 2, wherein the multiple LED sets further have:
multiple first slots, each first slot formed between adjacent two of the multiple LED sets; and
multiple second slots, each second slot formed between the LEDs of the LED sets aligned in two adjacent rows along the second direction.

4. The dot matrix LED light source as claimed in claim 3, wherein the multiple second electrodes of the second electrode assembly correspond to and cover the respective second slots.

5. The dot matrix LED light source as claimed in claim 4, wherein the second electrode assembly further has:
a second insulation layer formed on top surfaces of the multiple second electrodes and the first insulation layer; and
a grating layer formed on a top surface of the second insulation layer and having multiple gratings blocking the respective first epitaxial platforms of the multiple LED sets and the respective first slots.

6. The dot matrix LED light source as claimed in claim 5, wherein a packaging area is formed around a perimeter of the multiple LED sets and includes a first area and a second area, wherein the first area is aligned in the first direction with multiple first electrode terminals formed on the first area and connecting with the respective first electrodes of the first electrode assembly, and the second area is aligned in the second direction with multiple second electrode terminals formed on the second area and connecting with the respective second electrodes of the second electrode assembly.

7. A method for fabricating a dot matrix light-emitting diode (LED) light source for a wafer-level microdisplay, comprising:
preparing a substrate;
forming an LED epitaxial layer on a top surface of the substrate;
forming multiple LED sets arranged at spaced intervals by applying an LED wafer fabrication process to the LED epitaxial layer, wherein each LED set has multiple LEDs aligned in a first direction, each LED set has a first epitaxial platform, and the LEDs of the multiple LED sets that are aligned along any two adjacent rows in a second direction are aligned with each other;
forming a first electrode assembly on top surfaces of the first epitaxial platforms of the multiple LED sets; and
forming a second electrode assembly on top surfaces of the LEDs of the multiple LED sets aligned in the second direction.

8. The method as claimed in claim 7, wherein the LED wafer fabrication process adopts and combines a photolithography process, an etching process, a lift-off process, a thin film deposition process, a coating process, a wafer bonding process, a wafer laser de-bonding process, a laser lift-off process, a metal deposition process, and an alloy process.

9. A dot matrix light-emitting diode (LED) light source for a wafer-level microdisplay, comprising:
a substrate;
an LED epitaxial layer formed on a top surface of the substrate and having multiple LED sets formed on the LED epitaxial layer and arranged at spaced intervals, wherein each LED set has multiple LEDs aligned in a first direction, each LED has a first epitaxial layer, a light-emitting layer and a second epitaxial layer, the first epitaxial layers of the LEDs of each LED set are connected to form a first epitaxial platform, and the LEDs of the multiple LED sets that are aligned along any two adjacent rows in a second direction are aligned with each other;
a bonding layer formed between the substrate and the multiple LED sets;
a first electrode assembly formed between the bonding layer and the multiple LED sets and having multiple first electrodes each of which is formed between a corresponding LED set and the bonding layer to connect in series to the LEDs of the corresponding LED set; and
a second electrode assembly having multiple second electrodes, wherein each second electrode is formed on top surfaces of the LEDs of the multiple LED sets aligned in a corresponding row along the second direction to connect the LEDs of the multiple LED sets aligned in the corresponding row along the second direction.

10. The dot matrix LED light source as claimed in claim 9, wherein the first electrode assembly further includes:
a first insulation layer formed on a top surface of the first epitaxial layer and portions between each adjacent two of the multiple first electrodes, wherein top surfaces of the multiple LED sets are partially exposed for the multiple first electrodes to be formed on the exposed portions of the top surfaces of the multiple LED sets;
a reflective layer formed on the top surfaces of the multiple first electrodes and a top surface of the first insulation layer; and
a second insulation layer formed on a top surface of the reflective layer and the top surface of the first insulation layer.

11. The dot matrix LED light source as claimed in claim 10, wherein the reflective layer has multiple reflective strips correspondingly covering the respective first electrodes, the multiple reflective strips match and cover the respective LED sets to reflect light emitted from the multiple LED sets toward an upward direction.

12. The dot matrix LED light source as claimed in claim 11, wherein the second electrode assembly further includes a second insulation layer formed on top surfaces of the second electrodes and the first insulation layer, and the top surfaces of the LEDs of the multiple LED sets aligned in the second direction are partially exposed for the second electrodes to be respectively formed on the partially exposed portions of the top surfaces of the LEDs of the multiple LED sets aligned in the second direction.

13. The dot matrix LED light source as claimed in claim 12, wherein the multiple LED sets further have:
multiple first slots, each first slot formed between adjacent two of the multiple LED sets; and
multiple second slots, each second slot formed between the LEDs of the LED sets aligned in two adjacent rows along the second direction.

14. The dot matrix LED light source as claimed in claim 13, wherein the multiple second electrodes of the second electrode assembly correspond to and cover the respective second slots.

15. The dot matrix LED light source as claimed in claim 14, wherein the second electrode assembly further includes:
a second insulation layer formed on top surfaces of the second electrodes and the first insulation layer; and
a grating layer formed on a top surface of the second insulation layer and having multiple gratings covering the respective first slots.

16. The dot matrix LED light source as claimed in claim 15, wherein a packaging area is formed around a perimeter of the multiple LED sets and includes a first area and a second area, wherein the first area is aligned in the first direction with multiple first electrode terminals formed on the first area and connecting with the respective first electrodes of the first electrode assembly, and the second area is aligned in the second direction with multiple second electrode terminals formed on the second area and connecting with the respective second electrodes of the second electrode assembly.

17. A method for fabricating a dot matrix light-emitting diode (LED) light source for a wafer-level microdisplay as claimed in claim 7, comprising:
preparing a first substrate;
forming an LED epitaxial layer on a top surface of the substrate;
forming a first electrode assembly on a top surface of the LED epitaxial layer; and
preparing a second substrate;
forming a bonding layer on a top surface of the second substrate;
bonding the first electrode assembly to a top surface of the bounding layer;
forming multiple LED sets arranged at spaced intervals by applying an LED wafer fabrication process to the LED epitaxial layer, wherein each LED set has multiple LEDs aligned in a first direction, each LED set has a first epitaxial platform, and the LEDs of the multiple LED sets that are aligned along any two adjacent rows in a second direction are aligned with each other; and
forming a second electrode assembly on top surfaces of the LEDs of the multiple LED sets aligned in the second direction.

18. The method as claimed in claim 17, wherein the LED wafer fabrication process adopts and combines a photolithography process, an etching process, a lift-off process, a thin film deposition process, a coating process, a wafer bonding process, a wafer laser de-bonding process, a laser lift-off process, a metal deposition process, and an alloy process.
